(19) United States
(12) Patent Application Publication
(10) Pub. No.: US 2003/0000689 A1
(43) Pub. Date: Jan. 2, 2003

(54) Heat dissipater

(76) Inventors: Dah-Chyi Kuo, Sanchung City (TW); Chian Tao, Sanchung City (TW)

Correspondence Address: RABIN & CHAMPAGNE, PC, 1101 14TH STREET, NW, SUITE 500, WASHINGTON, DC, 20005, US

(21) Appl. No.: 09/894,145

(22) Filed: Jun. 29, 2001

(51) Int. Cl. F28F 7/00; F28D 15/00; H05K 7/20; H01L 23/34

(52) U.S. Cl. 165/185; 165/80.3; 165/104.33; 361/700; 257/715; 257/714

(57) ABSTRACT

A heat dissipater has a heat conductive device. The heat conductive device has a cavity therein. The cavity is filled with heat transfer medium. A plurality of heat transfer elements are installed in the heat conductive device. The heat conductive device is made of material with good conductivity, such as aluminum or copper. The heat transfer medium is a liquid in a normal temperature, such as paraffin, water, alcohol or mercury. The heat transfer medium is in contact with the heat source, the heat will be transferred to the heat transfer element of the heat conductive device so as to have the effect of heat conduction and dissipating.

### FIELD OF THE INVENTION

The present invention relates to a heat dissipater, and especially to plate shape heat dissipater having a preferred heat conductivity and low cost.

### BACKGROUND OF THE INVENTION

In the prior art, there are many different heat dissipating structures, which are primarily used in the heat dissipating elements. Herein, the electronic elements are central processing units in computers. The heat dissipating structure is used to dissipate heat generating from the electronic elements. As shown in FIGS. 1 and 2, in the heat source 1 of an electronic element, a heat conductive block is used to guide heat out. A heat dissipating body 12 formed with a plurality of fins are directly formed on the electronic element. Then the heat dissipating block 10 is installed with at least one heat tube 2. . A heat dissipating body 12 at another end of the heat pipe 2 is used to dissipate heat. The heat dissipating body 12 has fins 11 which are arranged as an array. The heat pipes are used as a medium for heat transfer. Heat is transferred from a heat source to the fins 11 of heat dissipating body 12.

The heat pipe 2 is a tight seal tube 20 with liquid 22 filled therein. The heat pipe 2 has liquid 22 for absorbing heat and then vaporizing to the heat dissipating body 12 for dissipating heat and then condensing. To be cycled more quickly, a wick structure 21 is installed in the tube. The wick structure 21 absorbs condensed liquid 22 quickly. The heat pipe 2 has a very good heat conductivity. However, it is complicated in manufacturing so that the cost is high.

Besides, as shown in the FIG. 2, the heat pipe 2 is embedded into heat conductive blocks 10. The heat conductive block 10 is installed with heat pipe groove 13. The heat pipe groove 13 must tightly match with the heat pipe groove 13. The gaps therebetween must be controlled severely for sustaining a preferred heat transfer. Thereby, heat at the bottom of the heat conductive block 10 can be transferred rapidly through heat pipes so as to be transferred from near the heat source to be far away from heat source.

This is because the heat conductivity of heat pipes 2 is superior than that of the heat conductive block 10 since under the consideration of cost, the heat conductive block 10 is mostly made of aluminum and is shaped by directly extrusion. Furthermore, it is light and is solid. The heat pipe is made of copper tube having a preferred heat conductivity. Therefore, in the prior art the gap between the outer surface of the heat pipe 2 and the inner surface of the heat pipe groove 13 is filled with heat conductive glue 23 which is also used to position heat pipe 2. The heat conductive glue 23 only partially reduces the heat transfer in the gap. This is because the heat conductive glue can not be too thick or too thin. Too thick has an effect of isolation so that the heat transferring rate is reduced. Too thin is difficult to enclose the heat pipes. The tightness between the heat conductive glue and heat pipe groove is not preferred. Thereby, gap is formed so that heat dissipating ability is effected.

If no heat conductive glue is used, the gap must be precisely combined. However, this need a very high cost and the assembly work is difficult. Since the matching of round tube and round groove needs a high roundness. If it is affected by temperature so as to deform, the heat pipe can not be inserted. As shown in the figures, an elliptic heat pipe and heat pipe groove are difficult in engagement.

When heat pipes are necessary to be bent, the cost is high. Under the consideration of cost, the aforesaid structure is not suitable.

### SUMMARY OF THE INVENTION

Accordingly, the primary object of the present invention is to provide a heat dissipater which is made integrally. Heat is transferred by heat convection. Not only the cost is down, but also the heat dissipating is good so as to be formed with a simple heat dissipating structure which is more easily combined to a heat pipe. The cavity in the present invention has any desired shape, which can be formed directly and suitable for bending pipes or vertical pipes. A short heat pipe is placed into the cavity and then the cavity is sealed. The heat transfer medium is used to transfer heat. Therefore, the heat convection is good through the heat transfer medium. Therefore, the heat dissipater can be made easily and assembled.

To achieve the objects, the present invention provides a heat dissipater having a heat conductive device. The heat conductive device has a cavity therein. The cavity is filled with heat transfer medium. A plurality of heat transfer elements are installed in the heat conductive device. The heat conductive device is made of material with good heat conductivity, such as aluminum or copper. The heat transfer medium is a liquid in a normal temperature, such as paraffin oil, water, methanol or mercury. The heat transfer medium is in contact with the heat source, the heat will be transferred to the heat transfer element of the heat conductive device so as to have the effect of heat conduction and dissipating.

The various objects and advantages of the present invention will be more readily understood from the following detailed description when read in conjunction with the appended drawing.

### BRIEF DESCRIPTION OF THE DRAWINGS

FIG. 1 is a perspective view of the prior art.

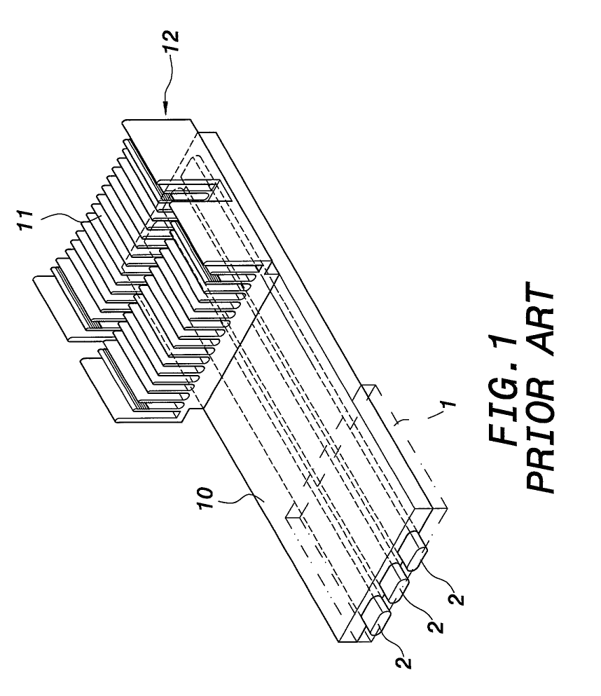

FIG. 2 is a cross sectional view of FIG. 1.

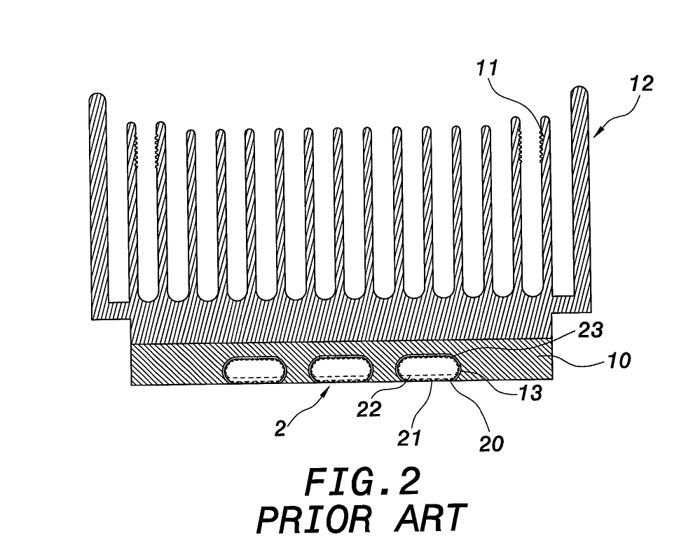

FIG. 3 is a perspective view of the present invention.

FIG. 4 is a cross sectional view of FIG. 3.

FIG. 5 is a cross sectional view of the FIG. 3 of the present invention, wherein heat is transferred.

FIG. 6 is a perspective view showing heat pipes are included in the cavity of the present invention.

FIG. 7 is a cross sectional view showing heat pipes being included in the cavity of the present invention.

### DETAILED DESCRIPTION OF THE PREFERRED EMBODIMENTS

To more understand the present invention by those skilled in the art, in the following, the details will be described with the appended drawings. However, all these descriptions are used to make one fully understand the present invention, while not to used to confine the scope of the present invention defined in the appended claims.

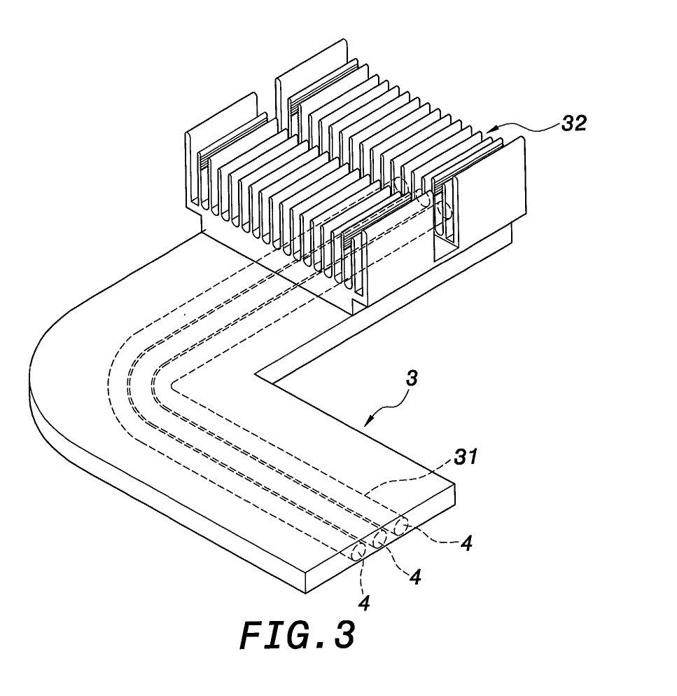

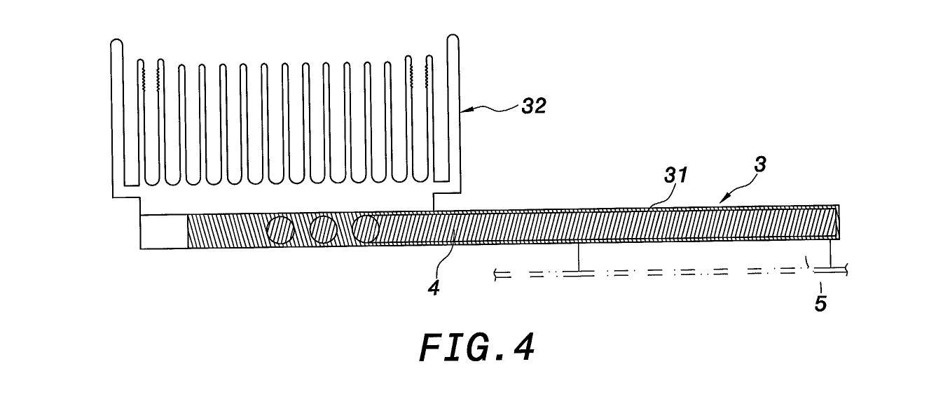

Referring to FIGS. 3 and 4, the heat dissipater of the present invention is illustrated. The heat dissipater has a heat dissipating device 3. A cavity 32 is formed within heat dissipating device 3. The heat dissipating device 3 is connected to a heat transfer element 32. The heat transfer element 32 can be integrally formed on the heat dissipating device. The cavity 31 is filled with heat transfer medium 4. The heat dissipating device 3 is made of material with preferred heat conductivity, for example, aluminum, copper, and other material. The heat transfer medium 4 is solid material in normal temperature (below 30 degree C., preferably, at 20 to 30 degree C.), such as wax or liquid material in normal temperature, such as paraffin oil, water, methanol, mercury, etc. When the heat dissipating device is in contact with the heat source 6, the heat of the heat source 6 is transferred to the heat transfer medium 4, so that the heat transfer medium 4 is heated to generate heat convection and then heat is transferred to the heat transfer element 32 of the heat dissipating device 3 so as to dissipate heat.

The heat transfer element 32 in the heat dissipating device 3 is installed as a fin structure arranged with an array. The surfaces of the fins have functions of heat dissipating. As shown in figures, a cavity with three strips parallel arranged is formed. Each cavity is received with different heat transfer mediums.

The most importance structure of the present invention is that the heat transfer medium is installed in the heat dissipating device. In general, the heat transfer medium can transfer heat rapidly. In the prior art, it is a heat tube. The heat transfer medium of the present invention is preferably a cheap material. In the following, wax is used as a description. The wax will be melted into liquid as temperature is above 40 degree C. Therefore, in normal temperature of 25 degree C., wax is a block shape solid.

When cavities are installed in the heat dissipating device, heat melting material can be filled into the cavity so as to fill the cavity completely. In general, the heat transfer medium is arranged at in a heat conductive device independently and has material different from the heat expanding device.

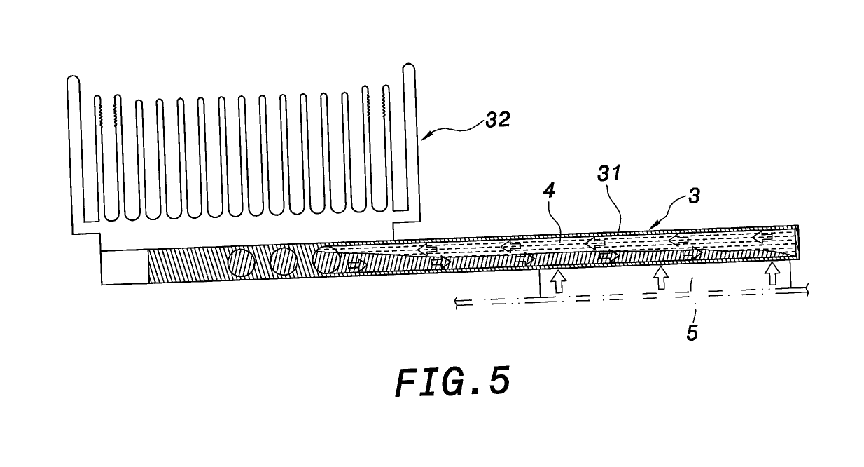

Referring to FIG. 5, the heat transfer medium, wax, near the heat source will heat and thus melted since wax will dissolve above 40 degrees. The liquid from melting wax will generate heat convention so that heat will transfer continuously from the heat source to the heat transfer element. Since no gasify space is formed in the heat conductive device. Therefore, the heat transfer material may be a liquid for heat transfer.

For water, alcohol and mercury in the normal temperature, the cavity must have a filling opening. The cavity has a preset space and has a filling opening. The opening must be sealed properly for filling with liquid heat transfer material.

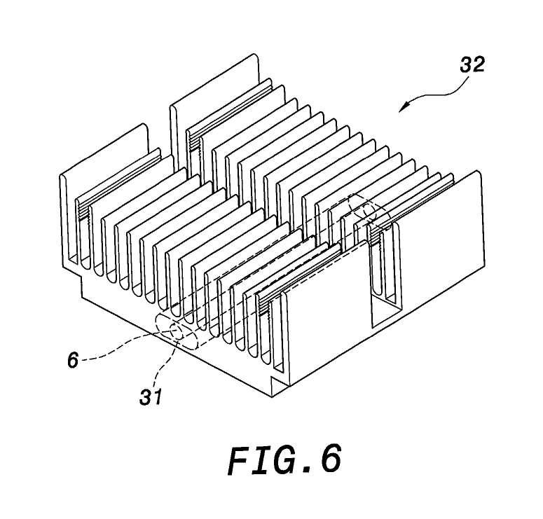

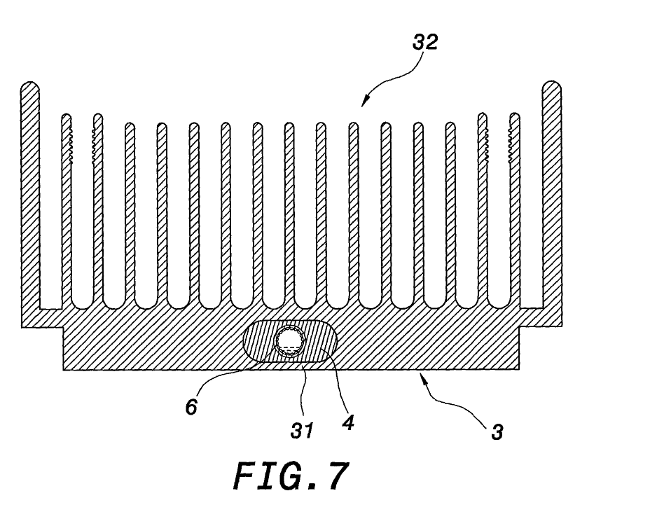

Besides, in another embodiment illustrated in FIGS. 6 and 7, at least one heat pipe 6 is included in the cavity 31. Respectively, the cavity 31 is presented as a non-round groove, such as an elliptical groove. When a heat pipe 6 is embedded into the heat transfer medium 4, since the heat transfer of the heat pipe 6 is superior than that of the heat transfer medium, the heat is transferred quickly. Furthermore, the cavity is unnecessary to be matched with the heat pipe. It is only necessary that the heat pipe can be passed into the cavity. The other space is filled with the heat transfer medium. Therefore, the heat transfer medium has a better heat transfer speed and the heat transfer of the heat conductive device is improved slowly. Therefore, the cavity has a curved shape as illustrated in FIG. 3 for embedded with a plurality of heat pipe. Therefore, the heat pipe can be serially connected one by one so as to have a preferred serial connected heat conductive means and be economical in manufacture.

Other than the aforesaid structure, in the present invention, the convention of the heat transfer medium is used, which is better than the heat conductive device, and is combined with the heat conductive device so as to save the cost in manufacturing and thus the product has a commercial worth. Since the heat transfer medium has a heat convention effect in the heat conductive device so as to have a function of transfer quickly. Any shape of cavity, such as curved shapes or continuous bending shapes, can be used. No heat conductive glue is necessary. The cavity can be used with the heat pipe so as to have a better utility to the present invention. The present invention is thus completely formed from the prior art.

Although the present invention has been described with reference to the preferred embodiments, it will be understood that the invention is not limited to the details described thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A heat dissipater comprising:
a heat conductive device having a cavity therein and being installed with a heat transfer element; and
a heat transfer medium filled in the cavity of the heat conductive device;
wherein when the heat conductive device is in contact with a heat source, heat will be transferred to the heat transfer medium so that the heat transfer medium is heated gradually so as to generate heat convention, and then heat is transferred to a heat transfer element of the heat conductive device so as to generate heat dissipation effect.

2. The heat dissipater as claimed in claim 1, wherein the heat conductive device is made of material with good conductivity, such as aluminum or copper.

3. The heat dissipater as claimed in claim 1, wherein the heat conductive device has a plate shape.

4. The heat dissipater as claimed in claim 1, wherein the heat conductive device has a heat transfer element made of heat dissipating fins.

5. The heat dissipater as claimed in claim 1, wherein the heat conductive device is installed with at least two cavities for receiving heat conductive device.

6. The heat dissipater as claimed in claim 5, wherein the heat transfer medium are made of different materials.

7. The heat dissipater as claimed in claim 1, wherein each heat transfer medium is a solid material in normal temperature, the heat transfer medium is wax.

8. The heat dissipater as claimed in claim 1, wherein the heat transfer medium is a liquid in a normal temperature, such as paraffin, water, alcohol or mercury.

9. The heat dissipater as claimed in claim 1, wherein the cavity is further has a heat tube.
